(19) United States
(12) Patent Application Publication
(10) Pub. No.: US 2009/0175006 A1
(43) Pub. Date: Jul. 9, 2009

(54) HONEYCOMB HEAT DISSIPATING APPARATUS

(76) Inventors: Rong-Yuan JOU, Da Li City (TW); Wen-Chieh Tseng, Hua Tan Township (TW); Ching-Jui Chen, Changhua City (TW)

Correspondence Address: RABIN & BERDO, P.C., Suite 500, 1101 14th Street, N.W., Washington, DC, 20005, US

(21) Appl. No.: 11/971,369

(22) Filed: Jan. 9, 2008

(51) Int. Cl. H05K 7/20

(52) U.S. Cl. 361/710

(57) ABSTRACT

A honeycomb heat dissipating apparatus made of a composite metal material includes honeycomb cells that are integrally formed by vacuum die casting, and continuous convex and concave distal surfaces disposed around the periphery of the heat dissipating apparatus, and an adjacent surface of each cell is a thin surface, and the heat dissipating apparatus can be in a standalone mode, or combined with other heat dissipating apparatuses. One or more honeycomb heat dissipating apparatuses can be installed on a circuit board or an electronic component of a lamp or an electric appliance, such that the heat dissipating apparatus can dissipate heat quickly by the honeycomb cells without occupying much space. The invention can increase the heat dissipating area for a faster heat dissipating effect and change the stylish appearance to achieve the aesthetic effect.

### BACKGROUND OF THE INVENTION

1) Field of the Invention

The present invention relates to a honeycomb heat dissipating apparatus, and more particularly to a heat dissipating apparatus integrally made of a composite metal material and in a shape of honeycomb cells, and a plurality of continuous convex and concave distal surfaces formed at the periphery of the heat dissipating apparatus, and an adjacent surface of each cell is a thin surface, such that after the heat dissipating apparatus is combined with a lamp or an electric appliance, the apparatus does not occupy much space, but it can quickly dissipate heat by increasing the heat dissipating area. The invention can provide various stylish looks to the installed heat dissipating apparatus.

2) Description of the Related Art

Referring to FIGS. 1A and 1B for a general heat dissipating structure used for a lamp or an electric appliance available in the market, the heat dissipating structure includes a base A and a plurality of fins B disposed on the base A, wherein the base A is made of copper, and the fins B are made of aluminum, and thus the material cost is high. Furthermore, it takes lots of manufacturing time for the assembling, and after the base A and the plurality of fins B are integrated, the base A is placed at a position that requires heat dissipation, such that the plurality of fins B separated from each other with an interval is used for dissipating the heat produced during the operation of a circuit board and electronic components by conduction, so as to prevent overheat or damages to the circuit board and electronic components. However, the present electronic products, particular desktop and notebook computers that contain fast-operating electronic components require fast heat dissipations for the electronic components. If a heat sink is unable to timely dissipate the heat, system crashes will occur very frequently, and the heat may burn or damage the electronic components, and even make the whole computer system unable to operate at all. Similarly, a lamp may be burned if heat cannot be dissipated timely. Regardless of the type of electric products, an appropriate heat dissipating device is required to avoid all kinds of problems as mentioned above.

In general, the base A is enlarged and the number of fins B is increased to improve the heat dissipating effect, but such arrangement will also increase the volume of the heat sink or make its installation impossible. Furthermore, the surface at each installation position is not necessary a plane, and thus increasing the level of difficulty for the installation of the heat sink. In some cases, the installation may affect other components, and result in an unsmooth operation. Obviously, the aforementioned prior art requires further improvements.

### SUMMARY OF THE INVENTION

In view of the shortcomings of the prior art, the inventor of the present invention developed a honeycomb heat dissipating apparatus in accordance with the present invention to overcome the shortcomings of the prior art.

An object of the present invention is to provide a honeycomb heat dissipating apparatus, comprising a plurality of honeycomb cells, and plurality of continuous convex and concave distal surfaces formed around the periphery, and an adjacent surface of each cell is a thin surface, such that after the heat dissipating apparatus is combined with a lamp or an electric appliance, the heat dissipating apparatus can dissipate heat quickly without occupying too much space.

An object of the present invention is to provide a honeycomb heat dissipating apparatus, wherein the honeycomb heat dissipating apparatus is made of various kinds of composite metal materials.

An object of the present invention is to provide a honeycomb heat dissipating apparatus, wherein the honeycomb heat dissipating apparatus comprises a plurality of honeycomb cells integrally formed by vacuum die casting, for reducing air holes, producing shrink holes, and refining the crystal structure to improve the precision of the shape and dimensions.

An object of the present invention is to provide a honeycomb heat dissipating apparatus, wherein a plurality of continuous convex and concave distal surfaces are formed around the periphery of the honeycomb heat dissipating apparatus for providing a close engagement for the installation of several heat dissipating apparatuses.

An object of the present invention is to provide a honeycomb heat dissipating apparatus, wherein the honeycomb heat dissipating apparatus includes a thin surface which is an adjacent surface of each cell for reducing the overall weight of the heat dissipating apparatus to meet the lightweight requirement of a compact design.

An object of the present invention is to provide a honeycomb heat dissipating apparatus, wherein the honeycomb heat dissipating apparatus is a single apparatus combined with a lamp or an electric appliance.

An object of the present invention is to provide a honeycomb heat dissipating apparatus, wherein a plurality of honeycomb heat dissipating apparatuses are combined with a lamp or an electric appliance, without having any gap or occupying much space, so as to increase the heat dissipating area for a faster heat dissipating effect.

An object of the present invention is to provide a honeycomb heat dissipating apparatus, wherein the honeycomb heat dissipating apparatus may come with different stylish appearance according to the installation position of a lamp or an electric appliance, and the heat dissipating apparatus is attached closely with the lamp or electric appliance to effectively conduct and dissipate heat.

An object of the present invention is to provide a honeycomb heat dissipating apparatus, wherein the honeycomb heat dissipating apparatus may vary its stylish appearance to give an aesthetic look to the heat dissipating apparatus.

### BRIEF DESCRIPTION OF THE DRAWINGS

FIG. 1A is a perspective view of a prior art;

FIG. 1B is a side view of a prior art;

FIG. 2A is a perspective view of the present invention;

FIG. 2B is a side view of the present invention;

FIG. 3A is a schematic view of a plurality of sets in accordance with the present invention;

FIG. 3B is another schematic view of a plurality of sets in accordance with the present invention;

FIG. 4A is a schematic view of a first preferred embodiment of the present invention;

FIG. 4B is a schematic view of a second preferred embodiment of the present invention;

FIG. 4C is a schematic view of a third preferred embodiment of the present invention;

FIG. 5A is a perspective view of another mode of the present invention;

FIG. 5B is a side view of another mode of the present invention;

FIG. 5C is a schematic view of another mode of the present invention;

FIG. 6 is a schematic view of a further mode of the present invention; and

FIG. 7 is another schematic view of a further mode of the present invention.

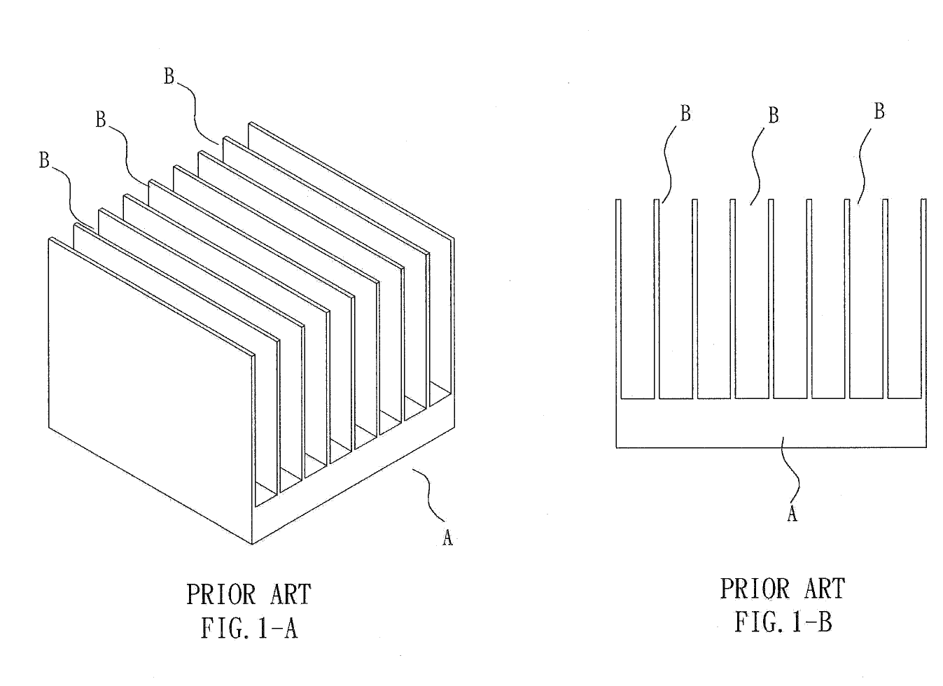

### DETAILED DESCRIPTION OF THE PREFERRED EMBODIMENTS

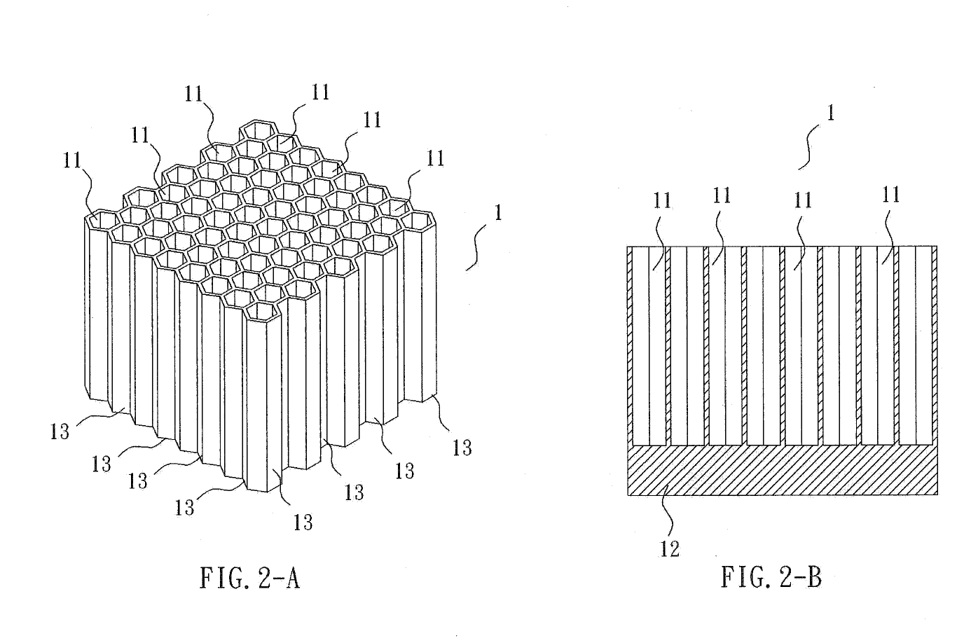

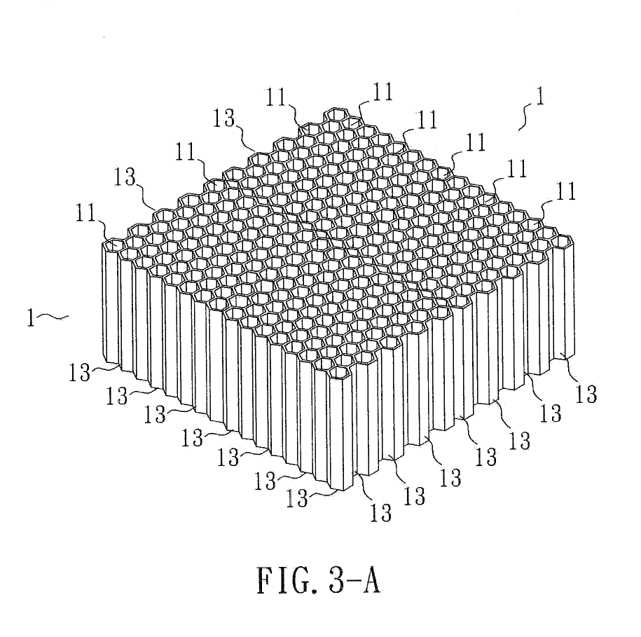

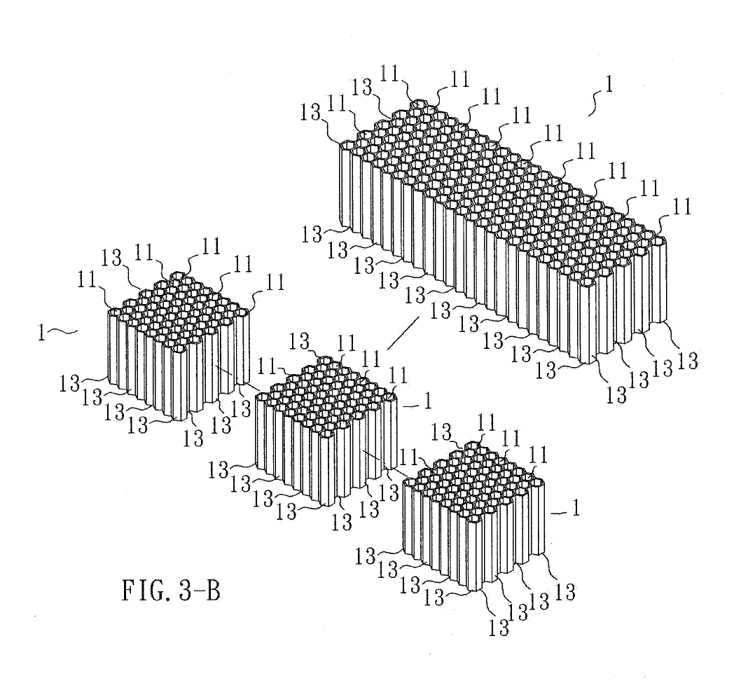

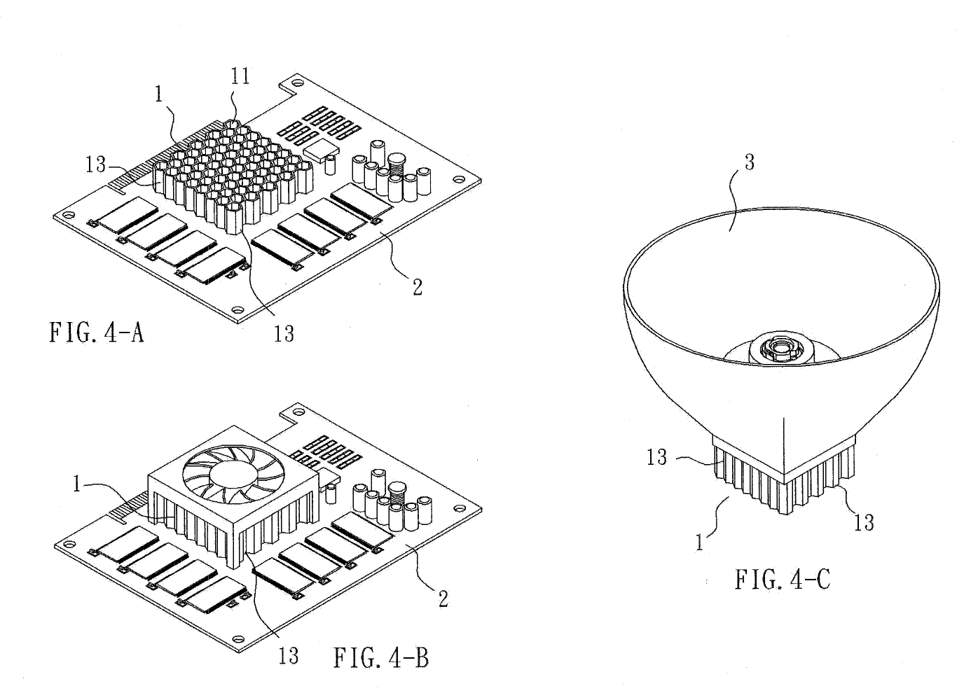

Referring to FIGS. 2A and 2B for the detailed description of a honeycomb heat dissipating apparatus of the present invention, the heat dissipating apparatus 1 is made of a composite metal material (such as zinc, aluminum, copper, and magnesium alloys) and comprised of a plurality of honeycomb cells 11 and a base 12 that are integrally formed by vacuum die casting, and a plurality of continuous convex and concave distal surfaces 13 is disposed around the periphery of the heat dissipating apparatus 1, and an adjacent surface of each cell 11 is a thin surface, wherein the heat dissipation coefficient of the heat dissipating apparatus 1 is calculated by a formula Thickness (T)/Pitch Length (L)=0.1˜0.2, and thus the heat dissipating apparatus 1 can be in a standalone mode or combined with other heat dissipating apparatuses 1 (as shown in FIGS. 3A and 3B). The heat dissipating apparatus 1 is coupled with a circuit board 2 in an electric product such as an electronic component (as shown in FIGS. 4A and 4B) and a lamp 3 (as shown in FIG. 4C). The heat dissipating apparatus 1 can quickly dissipate high heat through a plurality of honeycomb cells 11, without occupying much space.

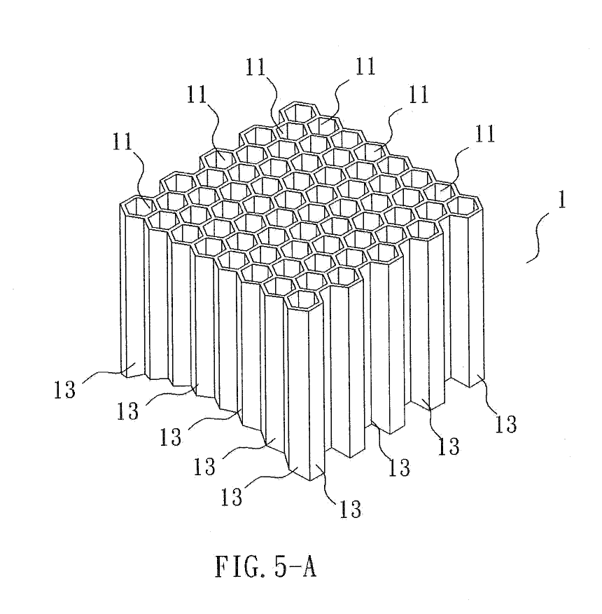

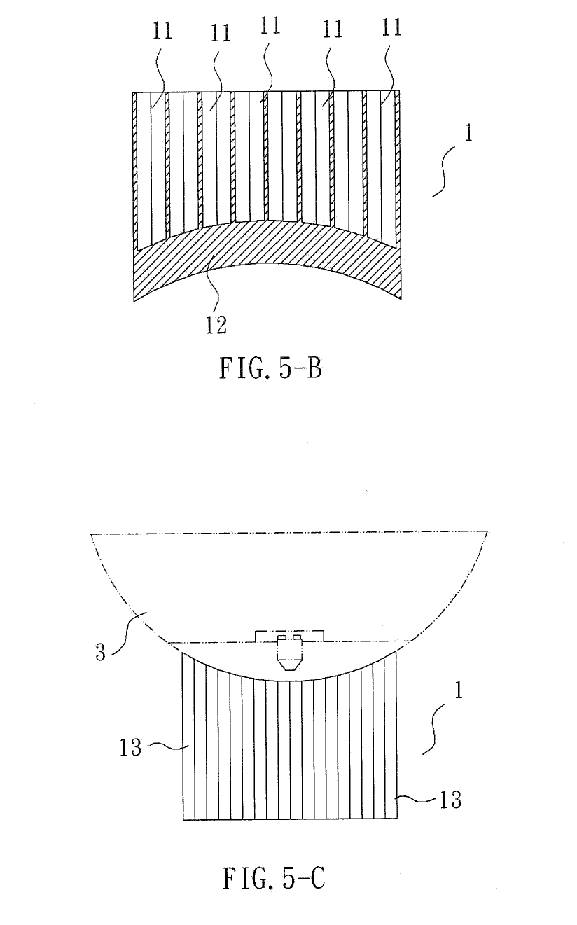

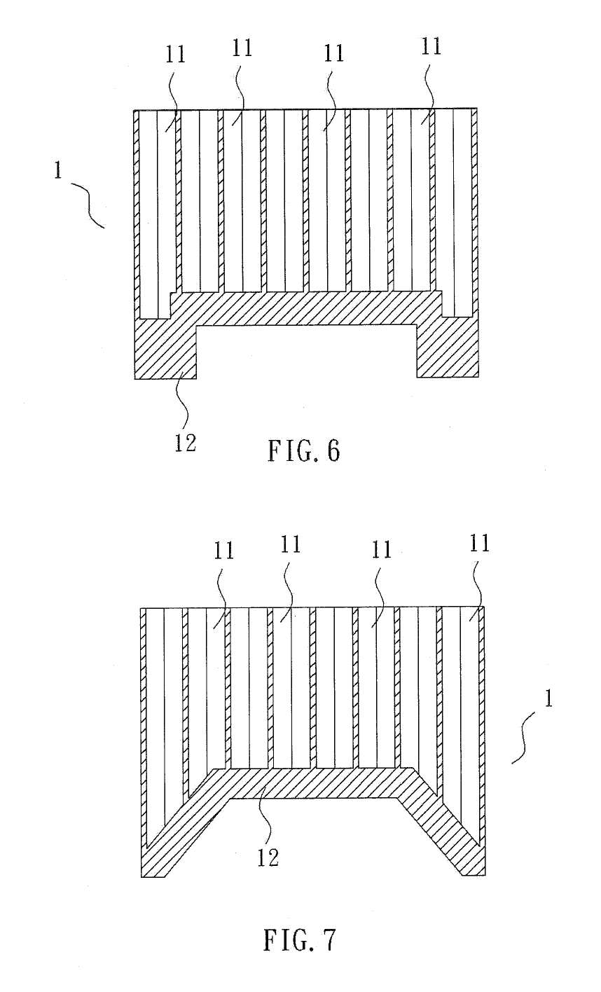

Since the heat dissipating apparatus 1 comprises a plurality of honeycomb cells 11 that are integrally formed by vacuum die casting, air holes can be reduced, and shrink holes can be produced in the manufacturing process, and the crystal structure can be refined to improve the precision of shape and dimensions. The heat dissipating apparatus 1 further comprises a plurality of continuous convex and concave distal surfaces 13 disposed around the periphery of the heat dissipating apparatus 1, for providing a close attachment for installing a plurality of heat dissipating apparatuses 1 with each other to give the best conduction effect. In addition, an adjacent surface of each cell of the heat dissipating apparatus 1 is a thin surface, so that the total weight of the heat dissipating apparatus is light. With a single heat dissipating apparatus, or several heat dissipating apparatuses coupled with each other, no gap is produced to occupy much space, and thus the heat dissipating area can be increased for a faster heat dissipating effect. The honeycomb heat dissipating apparatus 1 may vary its stylish look according to the installation position of the desired object (as shown in FIGS. 5A, 5B, 5C, 6 and 7) for a close attachment of the heat dissipating apparatus 1 onto the desired object in order to effectively achieve the conduction effect. Therefore, the heat dissipating apparatus 1 can change its stylish look to give an aesthetic design.

While the invention has been described by means of specific embodiments, numerous modifications and variations could be made thereto by those skilled in the art without departing from the scope and spirit of the invention set forth in the claims.

1. A honeycomb heat dissipating apparatus, comprising:
a plurality of honeycomb cells, made of a composite metal material and integrally formed by vacuum die casting;
a plurality of continuous convex and concave distal surfaces, disposed around the periphery of the honeycomb cells; and
a thin surface, being an adjacent surface of each cell;
thereby after the honeycomb heat dissipating apparatus is coupled with a lamp or an electric appliance, the honeycomb heat dissipating apparatus can dissipate heat quickly without occupying much space.

2. The honeycomb heat dissipating apparatus of claim 1, wherein the honeycomb heat dissipating apparatus comprises a plurality of honeycomb cells integrally formed by vacuum die casting for reducing air holes, producing shrink holes, and refining a crystal structure to enhance the precision of shape and dimensions.

3. The honeycomb heat dissipating apparatus of claim 1, wherein the honeycomb heat dissipating apparatus forms a plurality of continuous convex and concave distal surfaces around the periphery of the honeycomb heat dissipating apparatus, for providing a close attachment for an installation of a plurality of heat dissipating apparatuses.

4. The honeycomb heat dissipating apparatus of claim 1, wherein the honeycomb heat dissipating apparatus has a thin surface which is an adjacent surface of each cell, for reducing the overall weight of the heat dissipating apparatus to meet a lightweight requirement.

5. The honeycomb heat dissipating apparatus of claim 1, wherein a single honeycomb heat dissipating apparatus is combined with a lamp or an electric appliance.

6. The honeycomb heat dissipating apparatus of claim 1, wherein a plurality of honeycomb heat dissipating apparatuses are combined with a lamp or an electric appliance without producing a gap or occupying much space, so as to increase the heat dissipating area for a faster heat dissipating effect.

7. The honeycomb heat dissipating apparatus of claim 1, wherein the honeycomb heat dissipating apparatus may change its stylish appearance according to the installation position of the lamp or electric appliance, such that the honeycomb heat dissipating apparatus is attached closely with the lamp or electric appliance to effectively conduct and dissipate heat.
